(19) United States
(12) Patent Application Publication
(10) Pub. No.: US 2025/0317117 A1
(43) Pub. Date: Oct. 9, 2025

(54) SELF-REFERENCING MICROELECTROMECHANICAL SYSTEMS (MEMS) RESONATOR WITH DUAL MECHANICAL MODES FOR TEMPERATURE-INDEPENDENT ENVIRONMENTAL SENSING

(71) Applicant: Government of the United States as represented by the Secretary of the Air Force, Wright-Patterson AFB, OH (US)

(72) Inventors: Hengky Chandrahalim, Beavercreek, OH (US); David Lynes, Dayton, OH (US)

(21) Appl. No.: 19/198,745

(22) Filed: May 5, 2025

Related U.S. Application Data
(63) Continuation-in-part of application No. 18/503,804, filed on Nov. 7, 2023.
(60) Provisional application No. 63/382,730, filed on Nov. 8, 2022.
(60) Provisional application No. 63/383,963, filed on Nov. 16, 2022.
(60) Provisional application No. 63/486,312, filed on Feb. 22, 2023.
(60) Provisional application No. 63/661,206, filed on Jun. 18, 2024.

(51) Int. Cl. H03H 3/007; H03H 3/02; H03H 3/04; H03H 9/02; H03H 9/15; H03H 9/17

(52) U.S. Cl. CPC H03H 3/0078; H03H 3/02; H03H 3/04; H03H 9/02448; H03H 9/15; H03H 9/176; H03H 2003/027; H03H 2003/0414; H03H 2009/02496; H03H 2009/02527; H03H 2009/155

(57) ABSTRACT

A self-referencing, microelectromechanical system with dual mechanical modes for temperature independent environmental sensing including a resonator configured to resonate in a first fundamental width extensional mode and in a second contour mode, including: an input port; an output port; a top electrode comprising an aluminum chromium layer; a silicon-oxide layer; an aluminum-nitride layer; and an RF ground comprising a silicon layer. Upon passing a signal to the top electrode of the resonator, the top electrode and the RF ground establish an electric field to enable transduction through the piezoelectric, aluminum-nitride layer, and the resonator has adjacent contour modes close in frequency such that mechanical resonances of the resonator in differing resonance modes shift together as a function of temperature, the simultaneous shift of the mechanical resonances remaining constant across the temperature range enabling sensing of various criteria.

### CROSS-REFERENCE TO RELATED APPLICATIONS

Pursuant to 37 C.F.R. § 1.78(a)(4), this application claims the benefit of and priority to prior filed co-pending Provisional Application Ser. No. 63/661,206, filed Jun. 18, 2024, and is a continuation-in-part of co-pending Utility patent application Ser. No. 18/503,804, filed Nov. 7, 2023, which claimed priority to expired Provisional Application Ser. Nos. 63/382,730 filed Nov. 8, 2022, 63/383,963 filed Nov. 16, 2022, and 63/486,312 filed Feb. 22, 2023, each of which is expressly incorporated herein by reference in its entirety.

### RIGHTS OF THE GOVERNMENT

The invention described herein may be manufactured and used by or for the Government of the United States for all governmental purposes without the payment of any royalty.

### FIELD OF THE INVENTION

The present invention relates generally to microelectromechanical systems and, more particularly, to self-referencing microelectromechanical systems with dual mechanical modes for temperature-independent environmental sensing.

### BACKGROUND OF THE INVENTION

Piezoelectrically transduced microscale resonant devices have diverse applications, including inertial sensing, radio frequency (RF) signal processing, and environmental monitoring. Microelectromechanical systems (MEMS) resonators may be ideal for low-power, compact, and cost-effective sensing due to their small size and low power consumption. These microscale piezoelectric resonators can be extensively employed for frequency filtering, sensing, and clock generation within these fields. They can cover a broad frequency range and actuate various vibrational modes, such as extension, thickness, shear, and flexure, while achieving high selectivity, narrow bandwidth, and excellent stability. As handheld and Internet of Things (IoT) devices continue to shrink, the lightweight, low-power, high-frequency range, and multimode capabilities of micro- and nano-scale resonators have garnered significant research interest.

However, manufacture and implementation of microscale resonant devices is not without challenges. For instance, certain piezoelectric materials display sputtering deposition temperature requirements that make them unsuitable for deposition in many instances. Moreover, some piezoelectric materials (e.g., lead zirconate titanate (PZT), etc.) contaminate cleanroom environments or equipment or may require a post-deposition poling step. Accordingly, MEMS resonators incorporating different materials in new formations may be required.

### SUMMARY OF THE INVENTION

The present invention overcomes the foregoing problems and other shortcomings, drawbacks, and challenges of microelectromechanical systems. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention a self-referencing, microelectromechanical system (MEMS) with dual mechanical modes for temperature independent environmental sensing comprises: a resonator configured to resonate in a first fundamental width extensional mode (1st WEM) and to resonate in a second contour mode (2nd CM), comprising: an input port; an output port; a top electrode comprising an aluminum chromium layer; a silicon-oxide layer; an aluminum-nitride layer; and an RF ground comprising a silicon layer. Upon passing a signal to the top electrode of the resonator, the top electrode and the RF ground establish an electric field to enable transduction through the piezoelectric, aluminum-nitride layer, and the resonator has adjacent contour modes close in frequency such that mechanical resonances of the resonator in differing resonance modes shift together as a function of temperature over a temperature range from −200 C to +200 C, the simultaneous shift of the mechanical resonances remaining constant across the temperature range enabling sensing of various criteria including mass loading, stress, humidity, or chemical interactions.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 shows an experimental measurement system for measuring resonance of one or more microelectromechanical systems (MEMS), as shown and described herein.

FIG. 2 shows a planar view of a 1st fundamental width extensional mode (WEM) and a second contour mode 2nd (CM) showing that vibrations are in-plane for one or more MEMS.

FIG. 3 shows harmonic response results of various modes of vibrations for the resonance of various MEMS shown and described herein.

FIG. 4 shows top and cross-sectional views and scanning electron microscope images of various MEMS resonators.

FIG. 5 shows measured transmissions of MEMS resonators with and without an oxide layer.

FIG. 6 shows a temperature coefficient of frequency (TCF) for various MEMS resonators.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

Self-referencing microelectromechanical systems (MEMS) resonators with dual mechanical modes may be used for temperature-independent environmental sensing in systems. Dual mechanical modes in the context of MEMS resonators refers to distinct vibrational patterns or resonances in the physical structure of the resonator. Each mechanical mode may correspond to a unique pattern of deformation or displacement, characterized by its own resonant frequency, mode shape, and mechanical properties.

“Dual extensional modes” refer explicitly to two distinct mechanical resonance modes characterized primarily by deformation (extension or compression) occurring along specific dimensions (e.g., length or width) of the resonator structure. As disclosed herein, these dual extensional modes may include the fundamental Width Extensional Mode (1st WEM) and the Second Contour Mode (2nd CM). Each mode represents a unique, stable vibrational pattern with its specific resonant frequency. The term “extensional” indicates that the dominant mechanical motion involves structural elongation and contraction in-plane, along clearly defined axes of the resonator geometry. Defining “dual extensional modes” may explicitly establish the scope of mechanical resonance patterns that may be important to the invention's temperature-independent sensing. Embodiments disclosed herein may include devices designed with two distinct extensional-type resonant modes intentionally engineered to be adjacent (close in frequency), ensuring their simultaneous response to temperature changes and thus enabling inherent self-referencing capabilities.

In certain embodiments described herein, the “adjacent mechanical modes” may refer to two distinct yet closely spaced resonance modes: the 1st WEM and 2nd CM. These modes may be “adjacent” in the sense that their resonant frequencies are close enough to each other that environmental factors, including temperature changes, influence both modes sufficiently similarly. As a result, both modes shift in frequency concurrently and proportionally over temperature variations. This adjacency ensures that both mechanical modes experience comparable frequency shifts due to temperature variations, thus inherently preserving a stable frequency relationship between the modes. Consequently, this stable relationship enables self-referencing and temperature-independent sensing of environmental parameters such as mass loading, stress, humidity, or chemical interactions.

Mass loading can include, for example, immersion in or contact with different fluids that can alter viscous damping and mass loading effects, causing distinct shifts in the dual-mode resonances that depend on specific fluid properties. Additionally, mass loading may include specific biological binding events involving proteins, biomolecules, or microorganisms that can alter mass loading and/or induce surface stress, measurable via resonant frequency shifts.

The resonators disclosed herein may also be relevant in the sensing of external accelerations or vibrations applied to the resonator that can be detected and quantified through measurable shifts or modulation in both resonant frequencies and vibration amplitudes of the dual-mode resonances. Sensing of chemical interactions can include, for example, the sensing of chemically induced or environmentally driven corrosion and material degradation processes can affect structural integrity, resulting in detectable modifications of the resonant frequency characteristics. Additionally, stresses measured by the resonators can be related to long-term degradation processes, fatigue, or changes in structural integrity of the resonator that can alter its mechanical resonance properties. Such alterations can enable continuous health monitoring via measurable frequency shifts.

The phrase “adjacent mechanical modes” signifies that embodiments described herein leverage at least two mechanical resonance modes that are closely spaced in frequency. The adjacency of these modes can be significant because it directly contributes to the claimed benefit of temperature-independent environmental sensing. Specifically, the proximity in frequency ensures both modes respond similarly to temperature variations, thus providing inherent temperature compensation within the resonator device. This adjacency is not merely coincidental but deliberately engineered, distinguishing the claimed invention from conventional single-mode resonators or multi-mode resonators with widely separated frequencies. As used herein, the term “adjacent contour modes” refers to specifically designed or engineered contour mechanical modes characterized by closely spaced resonant frequencies. In particular, adjacent contour modes denote pairs of resonant frequencies wherein the second mode's frequency of vibration is less than about 35% away from the frequency of vibration of the first designed mode (i.e., if the first mode is at frequency x Hz, the second mode lies within the frequency range from x Hz to x+/−35% of x Hz). Preferably, adjacent contour modes denote pairs wherein the second mode's frequency is less than about 25% away from the frequency of the first designed mode. More preferably, adjacent contour modes refer to pairs wherein the second mode's frequency is less than about 15% away from the frequency of the first designed mode. This intentional proximity ensures effective self-referencing capability, enabling temperature-independent environmental sensing.

Ideally, this temperature-independent sensing method may provides a high benefit when the dual-mode resonances shift in opposite directions due to environmental effects (i.e., one resonance frequency shifts higher while the other shifts lower). However, there remains a possibility that both resonances may shift in the same direction (both to higher or both to lower frequencies). It should be understood that, even if both resonances shift in the same direction, the temperature effect can still be decoupled effectively. This decoupling is based on the known behavior that dual-mode resonances maintain a consistent frequency separation across a broad temperature range from −200° C. to +200° C. Therefore, effects arising from environmental parameters other than temperature can still be analyzed independently. For instance, even if both resonances shift upward or downward, one mode may shift farther or at a different rate than the other, enabling independent and accurate analysis of environmental parameters separate from temperature effects.

Additionally, as used herein, the term “close” refers to specifically designed or engineered contour mechanical modes characterized by closely spaced resonant frequencies. In particular, resonant frequencies wherein the second mode's frequency of vibration is less than about 35% away from the frequency of vibration of the first designed mode (i.e., if the first mode is at frequency x Hz, the second mode lies within the frequency range from x Hz to x+35% of x Hz). Preferably, adjacent contour modes denote pairs wherein the second mode's frequency is less than about 25% away from the frequency of the first designed mode. More preferably, adjacent contour modes refer to pairs wherein the second mode's frequency is less than about 15% away from the frequency of the first designed mode. This intentional proximity ensures effective self-referencing capability, enabling temperature-independent environmental sensing.

Embodiments disclosed herein may use Aluminum Nitride (AlN) as the primary piezoelectric material for transduction. Transduction refers to the process by which electrical signals are converted into mechanical vibrations (actuation), and conversely, mechanical vibrations are converted back into electrical signals (detection). Specifically, transduction is performed piezoelectrically by an AlN thin film. When a radio frequency (RF) electrical signal is applied across the electrodes, the piezoelectric AlN film mechanically deforms, generating resonant vibrations in the MEMS structure. Conversely, mechanical vibrations of the resonator induce mechanical stress in the AlN film, which is converted back into an electrical output signal.

Some embodiments may include scandium-doped AlN. Scandium doping of AlN may significantly enhance the piezoelectric properties of AlN, resulting in higher electromechanical coupling coefficients. Higher electromechanical coupling translates directly into improved sensitivity, lower motional resistance, and higher efficiency of the resonators. Doping AlN with scandium can enhance electromechanical coupling while maintaining a high Quality Factor (Q-factor) or introducing ferroelectric behavior. Further, AlN has been effectively utilized in transducers for a diverse range of devices, including energy harvesters, acoustic devices, sensors, actuators, RF resonators, filters and duplexers, and accelerometers. It has also been successfully integrated as part of the gate dielectric in thin film transistors (TFT). The combination of CMOS and MEMS devices on a single chip results in reduced die size, lower power consumption, and decreased manufacturing costs.

Dual-mode AlN transduced MEMS resonators can be designed and characterized over a broad temperature range. For example, MEMS resonators can be designed and characterized from −200° C. to +200° C. In embodiments, a silicon oxide (SiO₂) thin film can be incorporated on MEMS resonators' to influence Q-factors and temperature coefficient of frequency (TCF). In such embodiments, the two adjacent mechanical modes may consistently shift together across an entire temperature range, enabling temperature-independent self-referencing for enhanced environmental sensing. The addition of the oxide film can increase the Q-factor of the resonators by more than 500%, significantly improving their sensitivity to various environmental phenomena.

AlN transduced thin plate resonators featuring dual extensional modes, with and without an oxide thin film are considered. Utilizing finite element analysis (FEA), the resonant frequencies and mode shapes of various designs can be accurately predicted. The resonators can be fabricated and subjected to extensive RF characterization across a wide temperature range from −200° C. to +200° C. RF characterization can refer to the systematic testing and measurement of MEMS resonator performance by applying and measuring RF and/or other high-frequency electrical signals. The primary purpose of RF characterization in as related to embodiments disclosed herein is to measure resonant frequency Q-factor, and motional resistance (Rₘ) of each mechanical mode. This characterization is conducted using a calibrated network analyzer and a cryogenic probe station, spanning a broad temperature range (e.g., from −200° C. to +200° C.). The means of RF characterization includes applying known RF input signals to the resonator and precisely measuring the transmitted or reflected signals. At least one outcome of this characterization process is a detailed understanding of how each resonant mode behaves under varying environmental conditions, particularly temperature, thus validating the temperature stability and self-referencing capability of the resonator.

In embodiments, results demonstrate a significant enhancement in the Q-factor, larger than 500%, when an oxide layer is added. This improvement may be observed in the 70-80 MHz bulk acoustic wave (BAW) modes, particularly in the adjacent second contour mode (2nd CM) and fundamental width extensional mode (1^{st} WEM). Notably, AlN resonators on silicon may exhibit a temperature coefficient of frequency (TCF) similar to that of silicon carbide (SiC), approximately −30 ppm/° C. at room temperature. This TCF may be well within the +50 ppm/° C. range suitable for timekeeping applications in portable wireless devices.

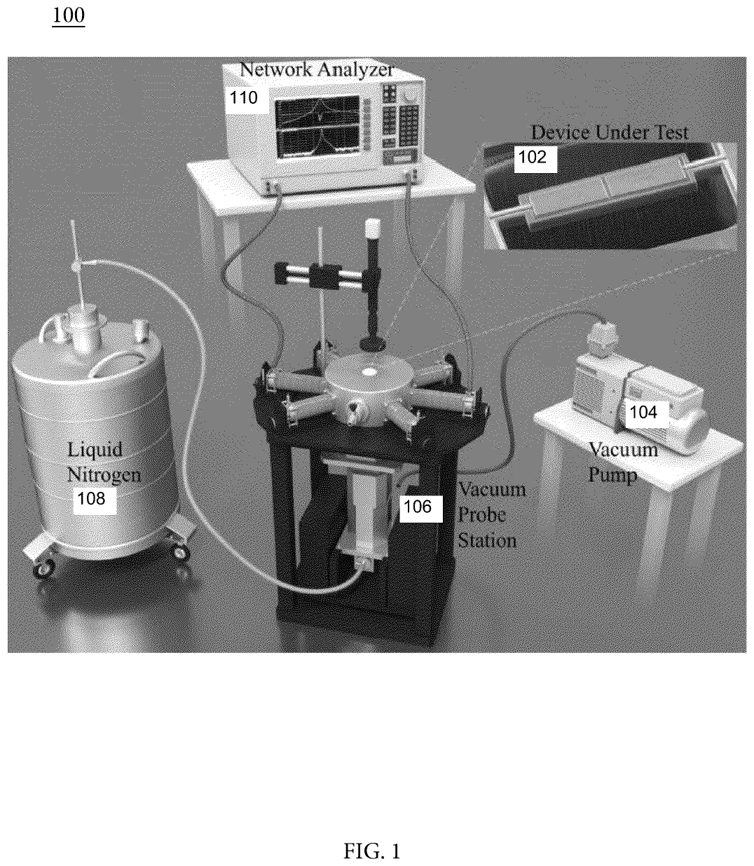

FIG. 1 shows an experimental measurement system 100 including a device under test 102, a vacuum pump 104, a vacuum, cryogenic probe station 106, liquid nitrogen 108, and a network analyzer 110.

The cryogenic probe station 106 (e.g., a cryogenic vacuum probe station) is used to provide a stable vacuum environment (e.g., approximately 1 μTorr) and precise temperature control across the broad temperature range of −200° C. to +200° C. The liquid nitrogen 108 serves as the cooling medium to achieve the cryogenic temperatures required for the lower temperature limits of testing. The vacuum pump 104 maintains the vacuum environment, reducing air damping effects and improving measurement accuracy. The microwave network analyzer 110 generates the RF input signals and measures the frequency response (S-parameters) of the resonators.

During testing, each resonator can be electrically probed individually within the vacuum probe station. A two-port Short-Open-Load-Through (SOLT) calibration is performed with the network analyzer to remove systematic measurement errors from cables and probes. Then, RF signals at the resonators' frequencies of interest (e.g., around 70-80 MHz) can be applied, and the transmitted signal (S21) response is measured. This process can be repeated individually for each resonator and each temperature step to determine key resonator performance metrics, including resonant frequency, Q-factor, motional resistance, and TCF.

In embodiments disclosed herein, multiple resonators may be fabricated on a single chip (e.g., a 1 cm×1 cm chip), and each resonator may be tested individually. During testing and in use, the resonators may not be electrically connected in parallel or in series. That is, each resonator on the chip can be electrically isolated and independently connected to the test probes during measurement. This individual, isolated configuration can prevent unintended coupling effects or electrical interference between devices, allowing each resonator's frequency response and performance to be clearly and accurately determined. This individual testing approach may be used to ensure accurate characterization of each resonator's specific mechanical resonance modes without interference or crosstalk from neighboring devices. Each resonator's response can be separately measured to clearly identify distinct resonant frequencies and Q-factors under controlled environmental conditions (e.g., temperature and pressure).

The two-port S-parameters of resonators operating in different contour modes can characterized under vacuum (e.g., 1 μTorr) using a Lake Shore cryogenic probe station and the network analyzer 110 (e.g., a microwave network analyzer, etc.) Measurements can be taken at 10° C. intervals across a temperature range of −200° C. to +200° C., with the network analyzer's RF input power set to 0 dBm. A two-port SOLT (short-open-load-through) calibration can be performed to mitigate line and probe errors.

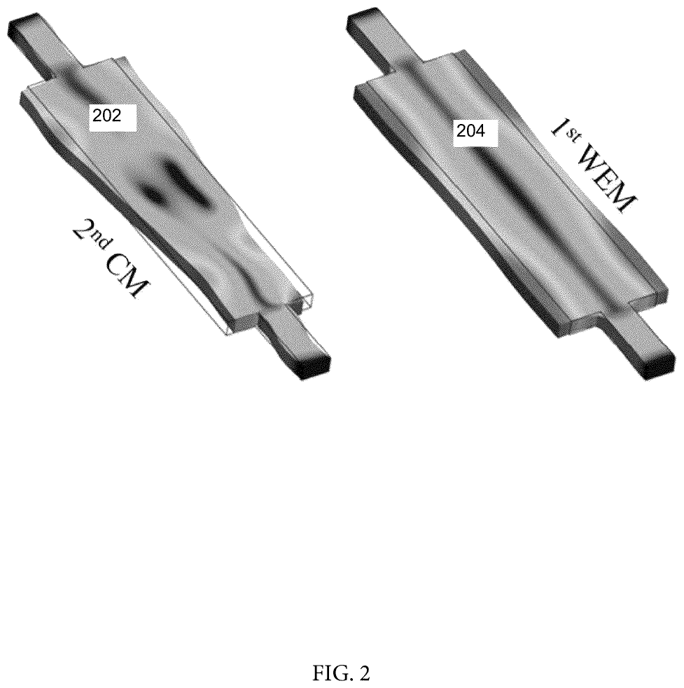

Referring to FIG. 2, the resonators 202, 204 can be any shape (e.g., rectangular, etc.) and may be designed to be driven in closely spaced contour modes by applying an RF signal across the top and bottom electrodes, thereby activating the d31 vibrational modes in the AlN. The d31 vibrational mode refers to a specific piezoelectric coupling mechanism in which an electric field applied across the thickness (direction 3 or vertical direction) of the AlN layer induces mechanical strain primarily in a perpendicular lateral direction (direction 1). This particular mode (d31) is advantageous because it effectively couples electrical energy to in-plane extensional mechanical vibrations, ideal for exciting the 1st WEM and the 2nd CM. Selecting the d31 piezoelectric effect can maximize efficient excitation of the resonator's targeted mechanical modes, enhancing the resonators' electromechanical coupling and overall sensitivity.

The shapes of the resonators shown in FIG. 2 represent FEA simulations depicting mechanical deformation patterns of two distinct resonant modes (1^{st} WEM and 2^{nd} CM), not physical resonator geometry differences. The resonators can be, in fact, physically identical rectangular structures. However, the illustrated tapered or distorted shapes in FIG. 2 demonstrate how each resonator mechanically deforms differently under resonance. The tapering or non-uniform appearance is merely indicative of the vibrational deformation of the resonators during operation-one end appears to taper because this represents the maximum displacement region in that specific resonant mode. Both resonators are uniform rectangles physically, but they display different deformation patterns due to the distinct mechanical modes excited. These depicted shapes are simulation representations of deformation modes and not physical shape distinctions in the device structure. The mode shapes presented visually exaggerate the mechanical displacements to clearly illustrate how different parts of the resonator deform when vibrating at their respective resonant frequencies. Thus, any perceived tapering is purely a simulation visualization effect, not representative of actual physical geometry.

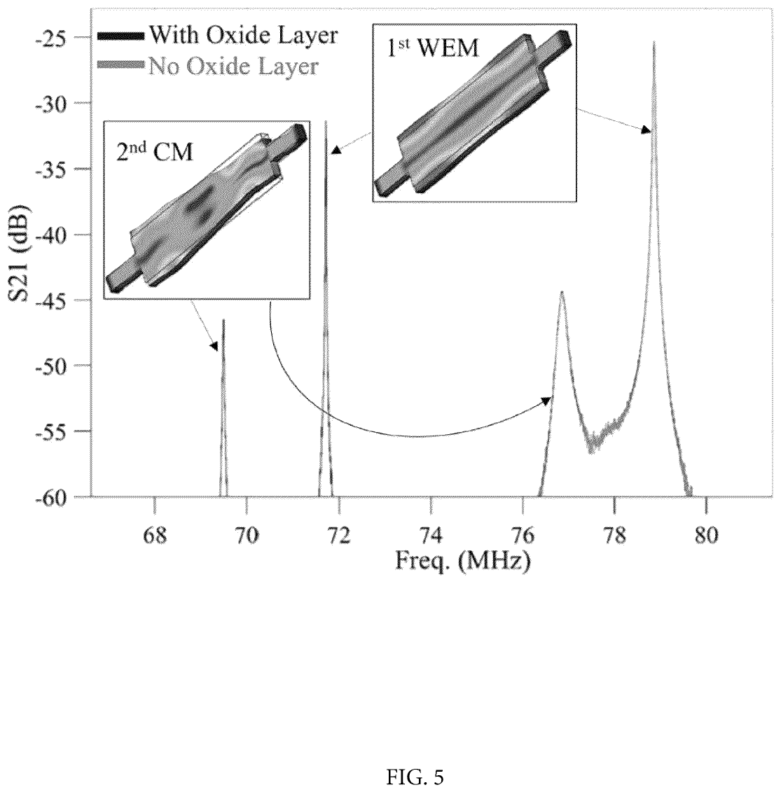

The darker vs. lighter regions in FIG. 2 (resonators 202 and 204) (and similarly in FIG. 5) indicate stress distribution. The dark central regions signify areas of maximum mechanical stress (nodal points), characterized by minimal or negligible displacement. Conversely, the lighter-colored ends indicate antinodal points, regions of maximum displacement with correspondingly lower stress. This visual shading helps clearly identify how mechanical stress and displacement are distributed across the resonator during operation, aiding the analysis and optimization of the resonator design.

The FEA simulations of FIG. 2 illustrate mechanical deformation patterns (mode shapes) at resonance. These mode shapes correspond specifically to the 1^{st} WEM and the 2^{nd} CM and are critically important because, as discussed otherwise herein, these two mechanical modes have resonant frequencies that are closely spaced. The proximity of these modes in frequency domain allows their simultaneous utilization for self-referencing, enabling temperature-independent environmental sensing.

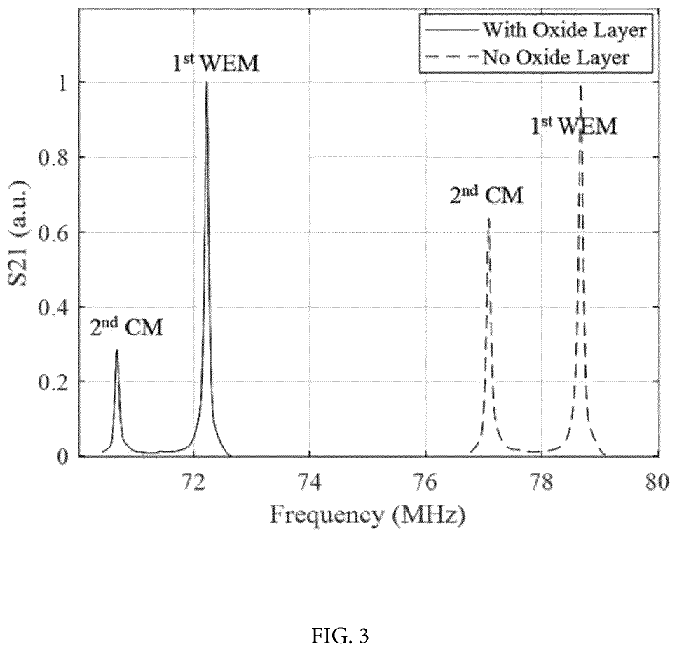

The 1^{st} WEM and 2^{nd} CM vibrations are in-plane, as illustrated in FIG. 2. FEA simulations may be conducted using ANSYS Mechanical, with material parameters listed in Table 1. Harmonic analysis can be performed, and S-parameters can be extracted from the calculated stress on the AlN geometry and plotted in FIG. 3.

TABLE 1

| | | | Acoustic |
|---|---|---|---|
| | Density | Young's | Velocity |
| Material | (kg m⁻³) | modulus (GPa) | (m s⁻¹) |
| Al | 2700 | 69 | 5055 |
| AlN | 3260 | 325 | 9984 |
| SiO₂ | 2465 | 70 | 5325 |
| Si | 2330 | 166 | 8440 |

The resonators may be fabricated using a fabrication process that utilizes piezoelectric materials for creating micro-devices based on a silicon-on-insulator (SOI) wafer and involving multiple lithography and etching steps to create structures with piezoelectric films. The process may utilize a design footprint constrained to 400×200 μm, inclusive of contact electrodes. Each resonator, measuring 220×60 μm and 12 μm thick, can be suspended by two anchors. The device structure may comprise a 10 μm thick n-type Si (100) layer serving as both the structural element and bottom conductor, overlaid with a 500 nm AlN piezoelectric transduction layer. In some embodiments, a 1.0 μm Al/20 nm Cr stack can form the top electrode.

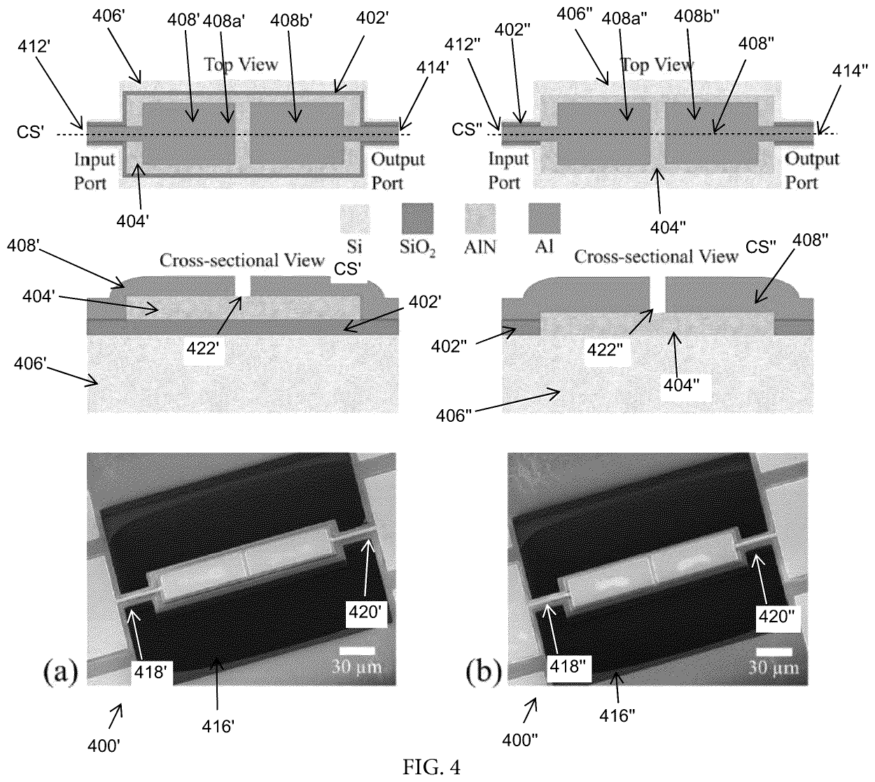

FIG. 4 shows two embodiments of a MEMS resonator 400 (designated 400′ and 400″ in FIG. 4(a) and FIG. 4(b), respectively). To investigate the influence of an oxide layer, two distinct designs of the resonators may be implemented. Each design includes an input port 412, an output port 414, an RF ground 406 (or “bottom electrode”) (which may be a Si element (or “layer,” generally interchangeably), a SiO₂ element 402, an AlN element 404, and a top electrode 408 (e.g., an Al—Cr element). Some embodiments may include a gap 422 between a first portion 408a and second portion 408b of the top electrode 408. The first and second designs are distinguished in FIG. 4(a) and FIG. 4(b), respectively, using a single prime (′) or a double prime (″) after the number identifier (e.g., 402′, 402″, etc.) The top electrode consists of a metal layer (i.e., Al—Cr) that directly applies the RF driving signal to the piezoelectric AlN film. The silicon substrate beneath serves as an RF ground plane, providing a defined reference potential (i.e., ground). The electric field required to activate the piezoelectric AlN is therefore established between the top metal electrode (signal electrode) and the silicon substrate (RF ground). This arrangement creates a clear, stable electric field through the AlN film, enabling effective piezoelectric excitation of the mechanical resonance.

In embodiments, the top electrode 408 may include, for example, an aluminum layer with an underlying chromium adhesion layer (“Al—Cr stack”) as the top electrode. However, it should be understood that embodiments may include top electrodes with other configurations, elements, etc. and embodiments are not limited to electrodes composed of aluminum and/or chromium. Electrodes can include, for example, other various conductive materials typically employed as electrodes in electronics, integrated circuits, or MEMS applications, such as, for example, gold (Au), titanium (Ti), platinum (Pt), molybdenum (Mo), and other similar metals or conductive materials. These and other elements and their combinations can be used effectively within the scope of disclosed embodiments. These alternative electrode materials similarly provide the necessary electrical conductivity and adhesion properties required to establish and maintain an electric field for piezoelectric transduction through the piezoelectric layer.

The input port 412 and the output port 414 are utilized for applying and extracting RF electrical signals. Specifically, the input port 412 applies an RF electrical signal into the resonator structure, and the output port 414 collects the resulting RF electrical signal after piezoelectric transduction. The transduction process converts the input electrical RF signals into mechanical vibrations and subsequently converts the mechanical vibrations back into electrical signals at the output. Thus, the input and output layers handle RF electrical signals that facilitate device operation.

The first design (FIG. 4(a)) can incorporate an SiO₂ layer 402′ between the AlN element 404′ and RF ground 406′. For example, the SiO₂ layer 402′ may be incorporated directly between the aluminum-nitride and silicon layers such that it contacts both the aluminum-nitride and silicon layers. In other embodiments, (e.g., the second design (FIG. 4(b)) the SiO₂ layer 402″ may be incorporated solely as an insulating layer between the top and bottom electrodes such that it is not between the AlN element and the silicon layer. In embodiments, the top electrode 408 and AN element 404 can remain consistent across both designs.

Some embodiments of include the gap 422. Embodiments including a break between a first portion 408a and second portion 408b of the top electrode (e.g., the gap 422) are considered two-port MEMS resonators. In a two-port configuration, the resonator has electrically isolated electrodes designated for input and output signals. Because MEMS resonators typically exhibit reciprocal behavior (meaning the roles of input and output electrodes are interchangeable), this gap physically separates the input electrode from the output electrode, allowing electrical signals to be distinctly applied to and sensed from opposite sides of the resonator.

When an electrical signal (e.g., RF signal) is applied to the input electrode, half of the top electrode generates an electric field vertically across the piezoelectric layer (AlN element 404), causing mechanical deformation due to the piezoelectric effect. This mechanical deformation, in turn, induces an electrical current, referred to as “motional current,” in the output electrode portion of the device. The presence of the gap 422 ensures that the motional current can be separately and clearly measured by the output electrode, allowing accurate characterization of the resonator's behavior in what is known as a transmission measurement.

It is important to note that the dual mechanical modes described in this invention (1^{st} WEM and 2^{nd} CM) can still be excited and observed even if no gap is provided between electrodes. In such a scenario (where the gap is absent), the device is called a “one-port configuration.” In the one-port configuration, a single electrode both applies the input signal and measures the response through reflection measurements rather than transmission. Although the specific characterization discussed herein used a two-port configuration (with the gap present), the fundamental inventive concepts of this disclosure (particularly the closely spaced dual mechanical modes enabling temperature-independent sensing) are fully applicable and effective in a one-port configuration as well.

The gap 422 between input and output electrodes can beneficial specifically in two-port configurations to facilitate clear measurement of resonator performance through transmission. However, the concept itself remains valid and functional irrespective of this gap, encompassing both one-port (reflection measurement) and two-port (transmission measurement) configurations.

The bottom sections of FIGS. 4(a) and 4(b) show scanning electron microscope (SEM) images of the fabricated resonators, illustrating the two configurations. The SEM images depict the actual physical resonator structure. These images clearly illustrate that the resonators are mechanically suspended bars, supported by two anchor points 418, 420 at each end of the bars. Surrounding each resonator device is an empty trench 416, created through selective etching during the fabrication process. This trench isolates the resonators mechanically from the surrounding substrate, allowing them to vibrate freely without mechanical interference.

Referring again to FIG. 2, the 2^{nd} CM and the fundamental WEM (or, “1^{st} WEM), respectively are shown. A consistent trend shows that the motional resistance (Rₘ) of the 1^{st} WEM is higher than that of the 2^{nd} CM. For both modes, an increase in temperature correlates with a decrease in resonant frequency (fᵣ) and Q-factor, accompanied by an increase in Rₘ. Notably, the resonator incorporating the oxide layer consistently exhibits superior Q-factors compared to the device without oxide, even at elevated temperatures. This enhanced Q-factor, along with the measured fᵣ of adjacent 2^{nd} CM and 1^{st} WEM for both resonator configurations, is clearly plotted in FIG. 5. Furthermore, the measurement results align well with the simulation results presented in FIG. 3.

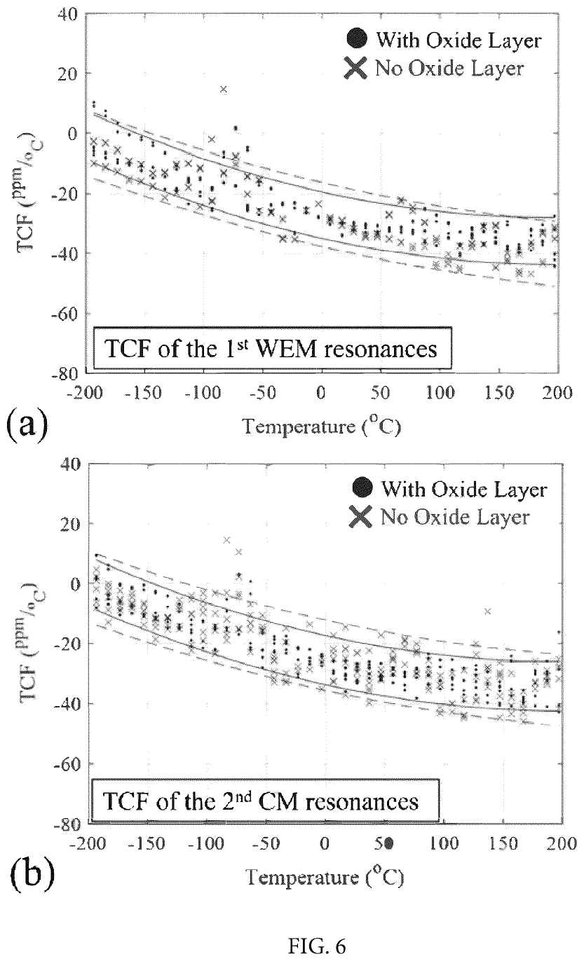

The TCF for the 1^{st} WEM vibrations is presented in FIG. 6(a) across the −200° C. to +200° C. range. At room temperature, the TCF measures-29.8 ppm/° C. for the resonator without oxide and −31.2 ppm/° C. for the resonator with oxide. Notably, the presence of the SiO₂ layer does not significantly alter the TCF across the evaluated temperature range. While the SiO₂ layer increases Rₘ by approximately 2 kΩ and slightly decreases fᵣ by 0.2% at room temperature, it significantly enhances the Q-factor. Q-factor improvements of up to 7000 points were observed. At room temperature, the resonator without the oxide exhibits a Q-factor of 1400, while the resonator with the oxide layer boasts a Q-factor of 8000, representing almost 6-fold improvement.

The results for the 2^{nd} CM are shown in FIG. 6(b). At room temperature, the resonator without the oxide layer exhibits a TCF of −26.4 ppm/° C., while the device with the oxide layer demonstrates a TCF of −28.4 ppm/° C. Overall, there are no significant differences in TCF behavior between the two configurations. Similar to the trend observed in the 1^{st} WEM, the addition of the SiO₂ layer approximately doubles the Rₘ. At room temperature, the Q-factor of the resonator without the oxide layer is 412, whereas the addition of the oxide layer boosts the Q-factor to 2400, representing a nearly sixfold enhancement.

In this study, MEMS resonators with two adjacent contour modes close in frequency were demonstrated. Both mechanical resonances shift together as a function of temperature, exhibiting similar performance trends over a wide temperature range. These dual-mode resonators offer several unique advantages, particularly in terms of temperature compensation. The simultaneous shift of both resonant frequencies with temperature ensures that their relative difference remains constant. This inherent temperature compensation is highly valuable, as it reduces the sensor's sensitivity to temperature variations, allowing it to focus on detecting other environmental perturbations. By analyzing the differential response of the two modes to environmental factors other than temperature, the sensor can achieve more specific and sensitive detection. For example, differences in how pressure, humidity, or chemical presence affect the two modes can be accurately distinguished by the sensor. This capability enhances the sensor's precision in identifying and quantifying various environmental conditions. Moreover, these dual-mode resonators may facilitate simultaneous measurement of multiple parameters. If one mode is more sensitive to mass loading and the other to stress or strain, the sensor can provide a comprehensive view of the environmental conditions. This multi-faceted sensing capability is particularly beneficial for applications requiring detailed and reliable environmental monitoring. The sensing capability is also beneficial for

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A self-referencing, microelectromechanical system (MEMS) with dual mechanical modes for temperature independent environmental sensing comprising:
a resonator configured to resonate in a first fundamental width extensional mode (1^{st} WEM) and to resonate in a second contour mode (2^{nd} CM), comprising:
an input port;
an output port;
a top electrode comprising an aluminum chromium layer;
a silicon-oxide layer;
an aluminum-nitride layer; and
an RF ground comprising a silicon layer, wherein
upon passing a signal to the top electrode of the resonator, the top electrode and the RF ground establish an electric field to enable transduction through the piezoelectric, aluminum-nitride layer, and
the resonator has adjacent contour modes close in frequency such that mechanical resonances of the resonator in differing resonance modes shift together as a function of temperature over a temperature range from −200 C to +200 C, the simultaneous shift of the mechanical resonances remaining constant across the temperature range enabling sensing of various criteria including mass loading, stress, humidity, or chemical interactions.

2. The self-referencing MEMS of claim 1, wherein the silicon-oxide layer is incorporated directly between the aluminum-nitride and silicon layers such that it contacts both the aluminum-nitride and silicon layers.

3. The self-referencing MEMS of claim 1, wherein the silicon-oxide layer is incorporated only as an insulating layer between the top electrode and the RF ground.

4. The self-referencing MEMS of claim 1, wherein the resonator is a rectangular resonator suspended within a trench by the input port and the output port.

5. The self-referencing MEMS of claim 4, wherein the trench is created through selective etching.

6. The self-referencing MEMS of claim 1, wherein the top electrode of the resonator comprises a 1 μm Al and 20 nm Cr stack.

7. The self-referencing MEMS of claim 1, wherein the 1^{st} WEM and 2^{nd} CM vibrations are in plane.

8. The self-referencing MEMS of claim 1, wherein the aluminum-nitride layer is doped with scandium.

9. The self-referencing MEMS of claim 1, wherein the top electrode is divided into a first portion and a second portion and the first portion and the second portion are separated by a gap.
